(19) United States
(12) Patent Application Publication
(10) Pub. No.: US 2014/0302656 A1
(43) Pub. Date: Oct. 9, 2014

(54) Method of Forming Ultra Shallow Junction

(71) Applicant: Shanghai Huali Microelectronics Corporation, Shanghai (CN)

(72) Inventor: TianJin XIAO, Shanghai (CN)

(73) Assignee: Shanghai Huali Microelectronics Corporation, Shanghai (CN)

(21) Appl. No.: 14/091,433

(22) Filed: Nov. 27, 2013

(30) Foreign Application Priority Data
Apr. 8, 2013 (CN) 201310119895.6

(51) Int. Cl. H01L 21/265; H01L 29/66

(52) U.S. Cl. CPC H01L 21/265; H01L 21/26586; H01L 29/66492
USPC 438/289

(57) ABSTRACT

The present invention discloses a method of forming ultra shallow junction, wherein the method includes the following steps: (1) providing a grid side wall etched semiconductor structure; (2) after the implantation of the nitrogen source ion into the said semiconductor structures, implanting the boron ions into the said structure of semiconductor by lightly doped drain (LDD) process; (3) forming an ultra shallow junction on the semiconductor structure by continuous processes of the heavily doped ions implantation and the anneal. The new source of N28 was introduced into this invention. N28 can reduce the diffusion of boron atom in the silicon substrate, and it can not interact with silicon atom to form the covalent bond. Hence, it overcomes problem of the aggravation of polysilicon gate depletion layer when carbon assisted ion implantation. Meanwhile, an ultra shallow junction is formed by simple process.

### CROSS-REFERENCE TO RELATED APPLICATIONS

The present application claims priority under the Paris Convention to Chinese application number CN 201310119895.6, filed on Apr. 8, 2013, the disclosure of which is herewith incorporated by reference in its entirety.

### FIELD OF THE INVENTION

The present invention relates to the field of Semiconductor device manufacturing, in particular it relates to a method forming an ultra shallow junction.

### BACKGROUND OF THE INVENTION

With the rapid development of the integrate circuits of large scale , the design of the integrate circuit is more and more complicated, and the integration level of the chips on the wafer becomes higher and higher. The size of the Metal Oxide Semiconductor (“MOS”, hereinafter) becomes smaller and smaller. MOS transistor is getting smaller and the gate is getting shorter. Consequently, the current channel below the gate is getting shorter. When the channel of MOS transistor is shortened to a certain extent, the short channel effect will occur. In theory, the length of the channel equals to the distance from the source electrode frontier to the drain electrode frontier. However, the effective length of channel is changed due to the effect depletion layer of the junction which is formed by a source electrode, a drain electrode and a substrate. When the length of the channel equals to or shorter than the depth of the depletion layer of junction, the depletion layer of the junction can invade the current channel, and as a result, the threshold voltage of gate will decrease, which is called the short channel effect. Because of the short channel effect, the threshold voltage of the device is very sensitive to the change of the length of the channel, and the electrical performance of devices is abnormal.

In the process technology node below 90 nm, the ultra shallow junction process is used to reducing the short channel effect of a Complementary Metal Oxide Semiconductor (“CMOS”, hereinafter). For a Positive channel Metal Oxide Semiconductor (“PMOS”, hereinafter), it is available to adopt carbon assisted implantation process for Light Doped Drain (“LDD”, hereinafter). In LDD process, the low energy boron ion is implanted. The ultra shallow junction is formed due to the reduction the diffusion of the boron atom in the silicon substrate. The carbon atom can reduce the diffusion of boron atom. Hence, the carbon assisted implantation process helps to form the ultra shallow junction.

However, in the LDD process, the polysilicon gate is also adopted carbon assisted implantation. And then, the carbon atom is implanted in the LDD art of the processes of heavily doped boron ion implantation of P type and the annealing. That will also reduce the diffusion of the boron atom which is implanted into the polysilicon gate in the P type heavily doped implantation. Consequently, the boron atom will not diffuse completely in the polysilicon gate. As a result, the concentration of the carrier which is in the polysilicon gate and near the junction of gate oxide is reduced. With the condition of combining bias on the polysilicon gate, it is easy to occur the situation that the carrier is exhausted which causes the condition of thickening the equivalent oxide layer, namely the problem of aggravation of polysilicon gate depletion layer.

Chinese Patent (Publication Number: CN101030602A) has disclosed a MOS transistor which can reduce the short channel effect and a method of producing the MOS transistor. Firstly, the trench is formed in the substrate.

Secondly, the ions are implanted into the substrate to form the well regions. The ions dopants are implanted into the well regions, which prevents the device from the punch through. The adjustment to the threshold voltage is implanted. Thirdly, the gate stack is formed in the trench. And then, ions are implanted into the substrate to form LDD. The side walls of the grid are formed. Then, ions are implanted into the substrate to form a source electrode and a drain electrode. Finally, the metal silicide layer is deposited upon the top of the source electrode and the drain electrode.

The method of the above invention can reduce the short channel effect, however, the process is complicated. It takes more time in mass production, and the costs of forming the trench are higher. As a result, all costs are increased.

Chinese Patent (Publication Number: CN101894748A) discloses a method of ion implantation. Firstly, germanium ions are implanted. Secondly, arsenic ions are implanted, and boron ions are implanted. Thirdly, boron ions are implanted, and then, indium ions are implanted. Finally, carbon ions are implanted.

The above invention provides a method of ion implantation. The method can lessen the negative influence that semiconductor component performance was affected by short channel effect. However, the species of the used ions are various. The energy can be hardly controlled in the implantation, and the processing steps are complicated. The method can't lessen short channel effect and raise the producing costs of devices.

### SUMMARY OF THE INVENTION

Based on the above problems, there is provided a method which forms an ultra shallow junction, in order to remove the short channel effect and to

improve the yield of the devices. Meanwhile, the process in the present invention is simplified; the present invention can decrease the costs of manufacturing. The method comprising:

A method forming an ultra shallow junction, which is applied to the process of ion implantation for forming PMOS, wherein the method comprises the following steps:
Step 1: providing a semiconductor structure which has been grid side wall etched and has been implanted by Halo ion (which is commonly known in the semiconductor industry);
Step 2: after the implantation of the nitrogen source ion into the said semiconductor structures, implanting the boron ions into the said structure of semiconductor by lightly doped drain (LDD) process;
Step 3: forming an ultra shallow junction on the semiconductor structure by continuous processes of the heavily doped ions implantation and the annealing;
   according to the above method, wherein the semiconductor structures comprises a silicon substrate and the gate structure, the gate structure is located on the upper surface of the substrate, where Shallow Trench Isolation regions (“STI”) and active regions locate, and the said active regions are located between the STI and the gate structure.

According to the above method, wherein the grid side wall etch process adopts dry etching.

According to the above method, wherein the ion source of Halo is Arsenic (As).

According to the above method, wherein the Halo ions implantation process are performed when the wafer is adjusted at an angle from 7° to 40° between the normal direction of the wafer and the direction of implanted ion ranges after adjusting the wafer, for example, 7°, 15°, 35° or 40°.

According to the above method, wherein the nitrogen in the Step 2 is N28.

According to the above method, wherein the implantation of nitrogen source ion and the implantation of boron ion in Step 2 are performed in order in the active regions and the gate structure.

According to the above method, wherein the above method, wherein the heavily doped ion implantation in the Step 3 is the implantation of source-drain ion regions.

According to the above method, wherein the ion source of the ion in the source drain ion implantation is boron (B) or boron fluoride (BF2).

According to the above method, wherein the heavily doped ions are implanted into the active regions and the gate structure in the Step 3.

The advantageous effects of the above technical solution are as follows:
The new source, i.e. N28 is used as substitute of carbon for assisted implantation. N28 can reduce the diffusion of boron atom in the silicon substrate, and nitrogen atom will not interact with silicon to form covalent bond, as a result, the present invention overcomes the worse problem of the aggravation of polysilicon gate depletion layer caused by carbon assisted ion implantation. Meanwhile, the ultra shallow junction is formed, where the processing is simple.

### BRIEF DESCRIPTION OF THE DRAWINGS

FIGS. 1 to 5 are structure diagrams of forming the PMOS which have the drain region and the source region with ultra shallow junction.

### DETAILED DESCRIPTION

The present invention will be further illustrated in combination with the following figures and embodiments, but it should not be deemed as limitation of the present invention.

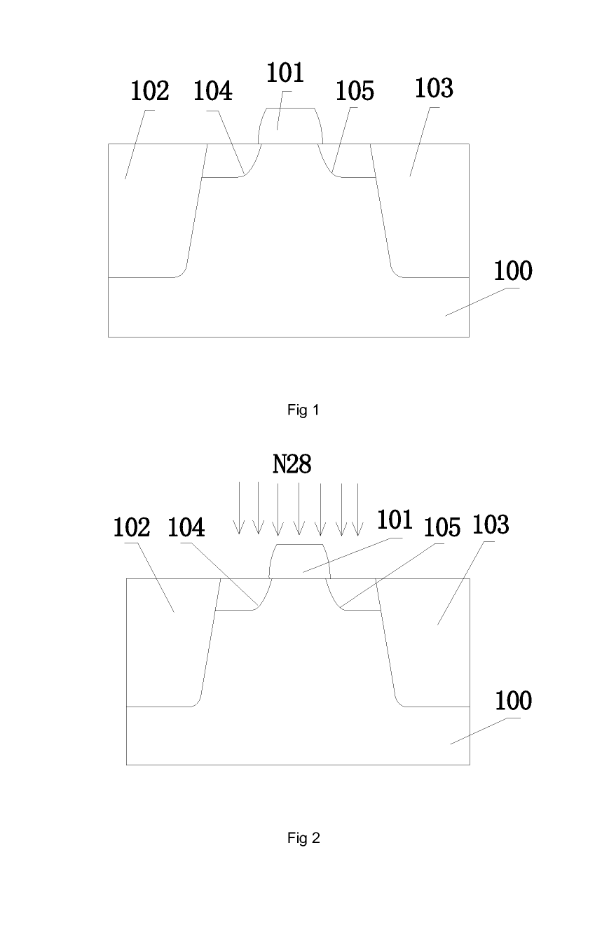

FIGS. 1 to 5 are structure diagrams of forming the PMOS which have the drain region and the source region with ultra shallow junction.

As shown in FIGS. 1 to 5, firstly, the spacer of a polysilicon gate is etched by dry etching. Then, when the angle of intersection between the normal direction of the wafer and the direction of the implanted ion is adjusted in the range from 7° to 40°, for example for example, 7°, 15°, 35°or 40°, the semiconductor structure as shown in FIG. 1 is formed through the implantation which forms Halo by Arsenic ions. The structure includes the Semiconductor Substrate 100, the first Shallow Trench Isolation 102 and the second Shallow Trench Isolation 103, and the Gate Structure 101 is formed on the Semiconductor Substrate 100. The semiconductor substrate between the shallow trench isolation and the gate structure acts as the active region. The first junction of Halo Ions Implantation 104 and the second junction of Halo Ions Implantation 105 are formed in the active region;

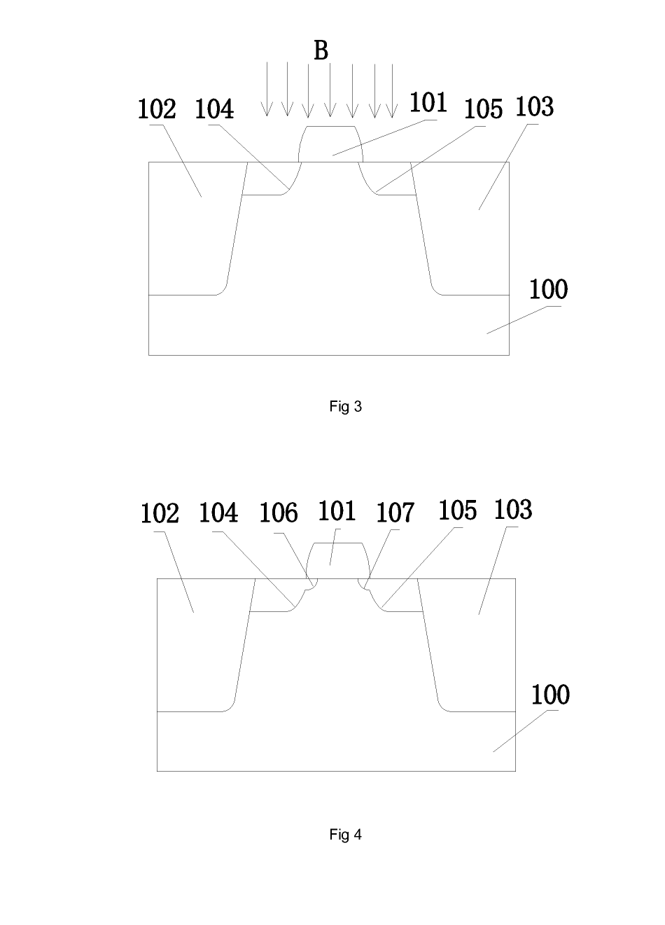

Then, N28 ions are implanted into the gate and the active region (as shown in FIG. 2), and boron ions are implanted into the gate and the active region to form lightly doped drain (as shown in FIG. 3), the first Ultra Shallow Junction 106 and the second Ultra Shallow Junction 107 are formed on the Substrate 100 (as shown in FIGS. 4).

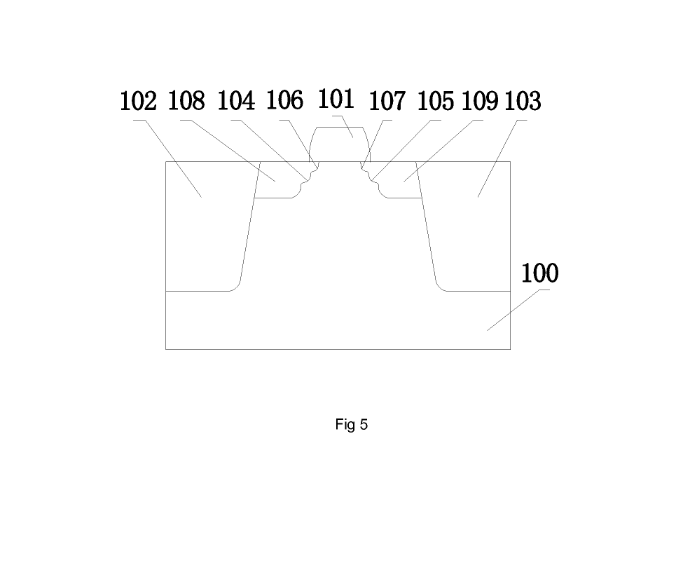

Then, B ions or BF2 ions are implanted into the gate and the active region, which forms the source region and the drain region, finally, the anneal process is performed in the source region and the drain region to form the PMOS which has the Source Electrode 108 with the first Ultra Shallow Junction 106 and the Drain Electrode 109 with the second Ultra Shallow Junction 107 (as shown in FIG. 5).

Embodiment 1: the ion-assisted implantation of N28 is applied to forming the ultra shallow junction.

In the 40 nm technology, the N28 assisted ion implantation is applied to forming the ultra shallow junction of which depth is 25 nm.

In conclusion, the new source—N28 is used as substitute of carbon for assisted implantation. N28 can reduce the diffusion of boron atom in the silicon substrate, and nitrogen atom will not interact with silicon to form covalent bond, as a result, the present invention overcomes the worse problem of the aggravation of polysilicon gate depletion layer caused by carbon assisted ion implantation. Meanwhile, the ultra shallow junction is formed, where the processing is simple.

It is obvious for the skilled in the art to make varieties of changes and modifications after reading the above descriptions. Hence, the Claims attached should be regarded as all the changes and modifications which cover the real intention and the range of this invention. Any and all equivalent contents and ranges in the range of the Claims should be regarded belonging to the intention and the range of this invention.

1. A method forming an ultra shallow junction, which is applied to the process of ion implantation for forming PMOS, wherein the method comprises the following steps:
Step 1: providing a semiconductor structure which has been grid side wall etched and has been implanted by Halo ion;
Step 2: after the implantation of the nitrogen source ion into the said semiconductor structures, implanting the boron ions into the said structure of semiconductor by lightly doped drain (LDD) process;
Step 3: forming an ultra shallow junction on the semiconductor structure by continuous processes of the heavily doped ions implantation and the annealing;
wherein the semiconductor structures comprises s a silicon substrate and the gate structure, the gate structure is located on the upper surface of the substrate, where shallow trench isolation regions(STI) and active regions locate, the said active regions are located between the STI and the gate structure.

2. The method according to claim 1, wherein the grid side wall etching are performed by dry etching.

3. The method according to claim 1, wherein the ion source of forming the Halo is Arsenic (As).

4. The method according to claim 3, wherein the Halo ions implantation process are performed when the wafer is adjusted at an angle from 7° to 40° between the normal direction of the wafer and the direction of implanted ion ranges after adjusting the wafer.

5. The method according to claim 1, wherein the nitrogen element in the Step 2 is N28.

6. The method according to claim 1, wherein the implantation of nitrogen source ion and the implantation of boron ion in Step 2 are performed in order in the active regions and the gate structure.

7. The method according to claim 1, wherein the above method, wherein the heavily doped ion implantation in the Step 3 is the implantation of source drain ion regions.

8. The method according to claim 7, wherein the ion source of the ion in the source drain ion implantation is boron (B) or boron fluoride (BF2).

9. The method according to claim 8, wherein the ion source of the ion in the source drain ion implantation is boron (B).

10. The method according to claim 1, wherein the heavily doped ions are implanted into the active regions and the gate structure in the Step 3.
